(19) United States
(12) Patent Application Publication
(10) Pub. No.: US 2015/0007865 A1
(43) Pub. Date: Jan. 8, 2015

(54) PHOTOVOLTAIC MODULE

(71) Applicant: SOLARWORLD INDUSTRIES SACHSEN GMBH, Freiberg (DE)

(72) Inventors: Stefan STECKEMETZ, Freiberg (DE); Jörg WALTHER, Chemnitz (DE); Martin KUTZER, Penig (DE); Alexander FÜLLE, Kirchberg (DE); Christian KOCH, Pohl (DE); Frederick BAMBERG, Freiberg (DE)

(21) Appl. No.: 14/319,840

(22) Filed: Jun. 30, 2014

(30) Foreign Application Priority Data
Jul. 2, 2013 (DE) 10 2013 212 845.2

(51) Int. Cl. H01L 31/0224; H01L 31/02; H01L 31/05

(52) U.S. Cl. CPC H01L 31/022433; H01L 31/0508; H01L 31/0201
USPC 136/244

(57) ABSTRACT

A photovoltaic module has a number of solar cells, which respectively include a contact structure on a pre-processed silicon wafer, which has a number of linear contact fingers disposed in parallel in a first direction and at least one bus bar disposed perpendicular to the first direction. The bus bar extends over the contact finger in a second direction and has a respective contact surface in the region of the contact finger, which protrudes above the contact finger in the second direction and is electrically connected to the contact fingers. At least one cell connector is provided for connecting the solar cells, which extends over the bus bar of at least one solar cell and is electrically connected to the contact surfaces of the bus bar, wherein the width of the cell connector is smaller than the length of the contact surface in the first direction.

The present invention relates to a photovoltaic module with a number of solar cells which have a front side contact structure that includes a number of linear contact fingers disposed in parallel and at least one bus bar extending perpendicular thereto.

Solar cells are used for the purpose of converting the energy of electromagnetic radiations, particularly sunlight into electrical energy. The energy conversion is based on the fact that the radiation in a solar cell is subjected to an absorption, whereby positive and negative charge carriers (“Electron-hole pairs”) are generated. The generated free charges are then isolated from each other, in order to be dissipated to isolated contacts.

Generally, solar cells have a square silicon substrate, in which two regions are configured with different conductivity or doping. There is a p-n junction between both the regions, which is also referred to as “Base” and “Emitter”. This p-n-junction generates an inner electrical field, which causes the above described isolation of the charge carriers generated by radiation.

Generally, the front side emitter-contact structure of the solar cell includes a grid-like arrangement made of linear metallic contact elements, which are also referred to as contact fingers. In addition, metallic bus bars extending transverse to the contact fingers and having a bigger width are provided. Generally, the rear side base-contact structure has a metallic layer configured flat, on which the metallic rear side contact elements are disposed. Cell connectors are connected to the front and the rear side contact elements.

A number of solar cells are always interconnected in a photovoltaic (PV) or solar module. Generally, the solar cells are interconnected in series via the cell connectors in so-called strings, which in turn are connected in the form of a series connection. The solar cells interconnected in this manner are located in a transparent embedded layer, which is disposed between a front side glass cover and a rear side film cover.

Generally, the cell connectors are tin-plated copper strips, which are soldered on the front side bus bars and the rear side contact elements. While attaching the cell connector to the front side bus bars, often there is an inaccurate positioning. Then, the cell connector is supported at least on one side on the contact fingers and exerts a force effect on the contact finger via the solder, which can lead to finger breakages and cell breakages in the bus bar region. The forces are developed on the contact fingers by different coefficients of thermal expansion of silicon substrate, metallizing paste, solder, copper strip, encapsulation material, rear side film or glass cover. The narrow sensitive contact fingers are often subjected to mechanical stress during cooling of the solder and during the lamination process on the solar module. Further mechanical stress develops by temperature fluctuations of day and night, summer and winter, as well as by snow and wind loads on the solar module. The finger breakages and cell breakages caused have a negative effect on the module output and increase the electrical degradation of the module. However, frequently the bus bars are also configured narrower than the cell connector in order to save silver paste. In these cases, there is mechanical stress on the fingers even without inaccurate positioning of the cell connector, because the cell connector exerts a force effect on the sensitive contact finger via the solder.

The object of the present invention consists of providing a photovoltaic module with a number of solar cells, which have an improved front side contact structure.

This object is achieved by a photovoltaic module according to claim 1. Further advantageous embodiments of the invention are claimed in the dependent claims.

According to the invention, the photovoltaic module has a number of solar cells, which respectively include a pre-processed silicon wafer with a contact structure that has a number of linear contact fingers disposed in parallel in a first direction and at least one bus bar disposed perpendicular to the first direction. The bus bar extends over the contact finger in a second direction and includes contact surfaces in the region of the respective contact fingers, which protrude over the contact finger in the first and in the second direction and are electrically connected to the contact fingers. Furthermore, at least one strip-like cell connector is provided; which extends over the bus bar and is electrically connected to the contact surfaces of the bus bars. The width of the cell connector is smaller in the first direction than the length of the contact surface in the first direction.

In accordance with the invention, the layout of the contact structure in the bus bars, which is used for combining the emitter-charge carriers detected over the contact fingers is configured in the form of broadened contact surfaces, which ensures that the cell connectors narrower in comparison to these contact surfaces do not come in mechanical contact with the contact fingers even in an inaccurate position by the attachment of the cell connector. Thus, by reliably preventing the plating of the cell connector on the contact fingers, the number of finger breakages and cell breakages can be reduced and thereby the risk of an electrical degradation of the solar cell and of the photovoltaic module made therefrom is reduced.

According to a preferred embodiment, the bus bar has a sequence of short and long contact surfaces in the direction of cell connector. The short contact surfaces serve for material-saving and thereby for a cost-reduction, since the contact surfaces are generally made of silver. At the same time, the shadow area of the solar cell front side, over which the incident light falls, is also reduced. The wider contact surfaces are used for an excellent electrical and mechanical contact between the cell connectors and the contact surfaces generally made of copper and reliably prevent the peeling-off of the cell connector from the contact surfaces at mechanical stress to which the solar cell or the photovoltaic module is subjected during manufacture or during use.

According to another preferred embodiment, the lengths of the contact surfaces in the region of the edges of the pre-processed silicon wafer with reference to the further contact surfaces of the bus bars is maximum. In particular, extremely high forces act on the cell connector in the region of the transition towards the solar cell mainly during the manufacture of the module, so that here there is an increased risk of a peeling off of the cell connector from the contact surfaces.

According to another preferred embodiment, the length of the contact surfaces is varied from the edge of the pre-processed silicon wafer towards the center of the pre-processed silicon wafer, such that the length of the contact surfaces in the direction of cell connector reduces and has a minimum preferably in the region of the center of the solar cell. By such a layout, an optimal compromise with reference to the material use, shadowing of the solar cell front side and sufficient adhesion is achieved on the contact surfaces at mechanical stress on the cell connectors.

According to another preferred embodiment, the corners of the contact surfaces are configured rounded-off or chamfered. This applies preferably also for the transitions of the contact surfaces towards the contact fingers. Thus, the stress peaks developed on the corners or in the transition region are avoided, which can lead to cell breakages. The same also applies to the rear side contact structure, the contact surfaces of which are likewise configured preferably rounded-off or chamfered, in order to avoid such stress peaks.

According to another preferred embodiment, the bus bars additionally have webs, which are narrower than the contact surfaces and interconnect these, wherein the transitions of the contact surfaces towards the webs are configured rounded-off or chamfered. By the additional webs under the cell connectors between the contact surfaces, there is a possibility to make an improved electrical and mechanical contact with the cell connectors, without requiring increasing peel-off of the solar cells front side by additional non-transparent contact layers, because the webs disappear under the always available cell connectors. Furthermore, the webs simplify the capacity of electrical contact of the solar cell by means of needle plates in the cell tester.

The invention is explained in more details in the following with the help of the Figures. They show:

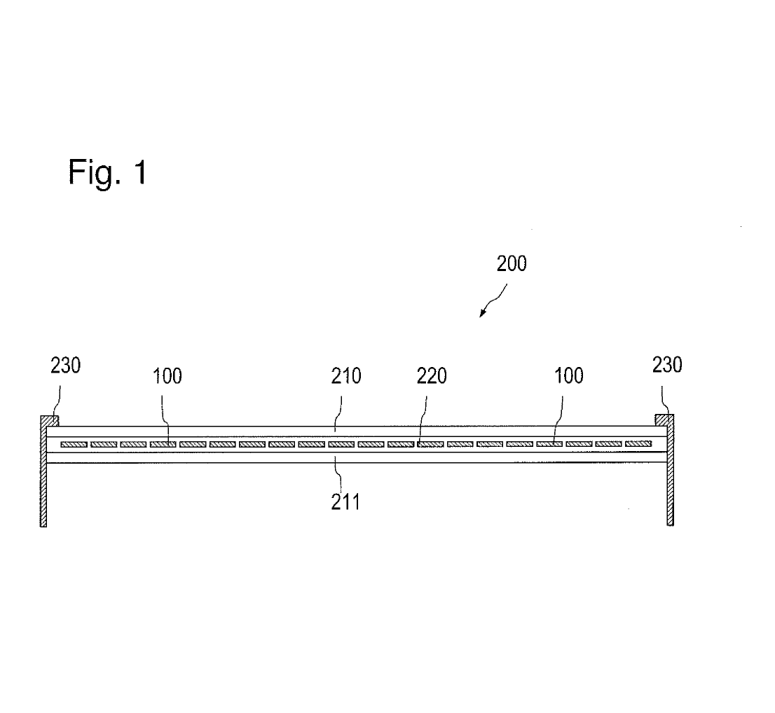

FIG. 1 shows a schematic lateral representation of a photovoltaic module;

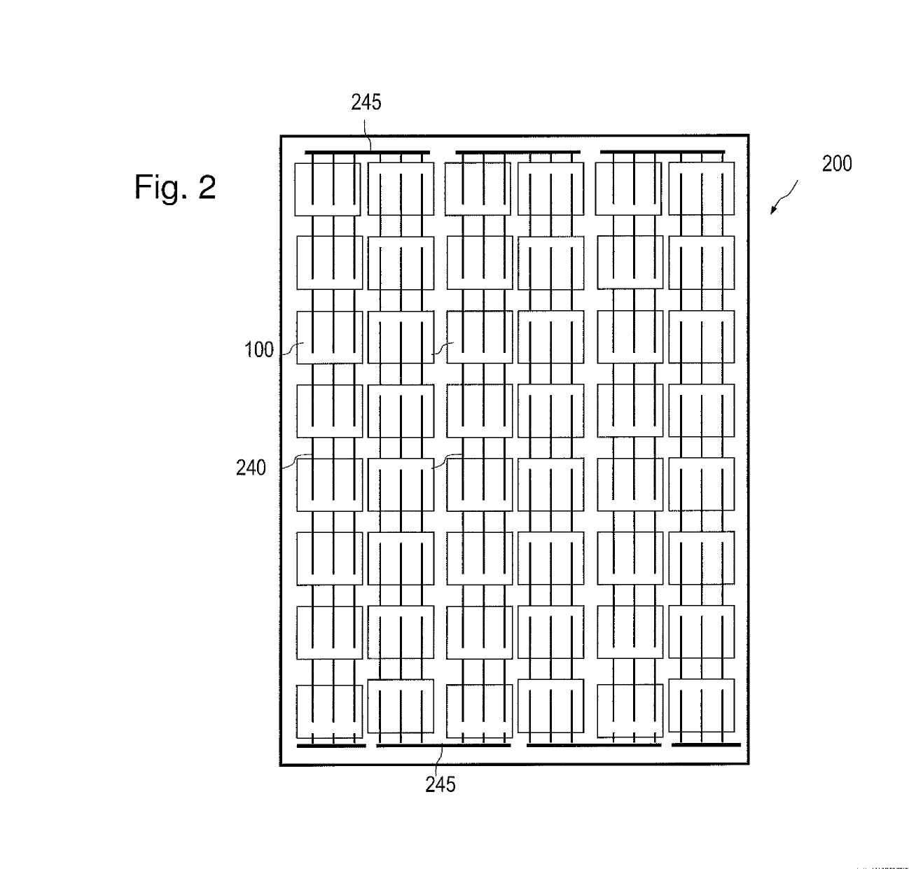

FIG. 2 shows a schematic top view representation of the photovoltaic module according to FIG. 1;

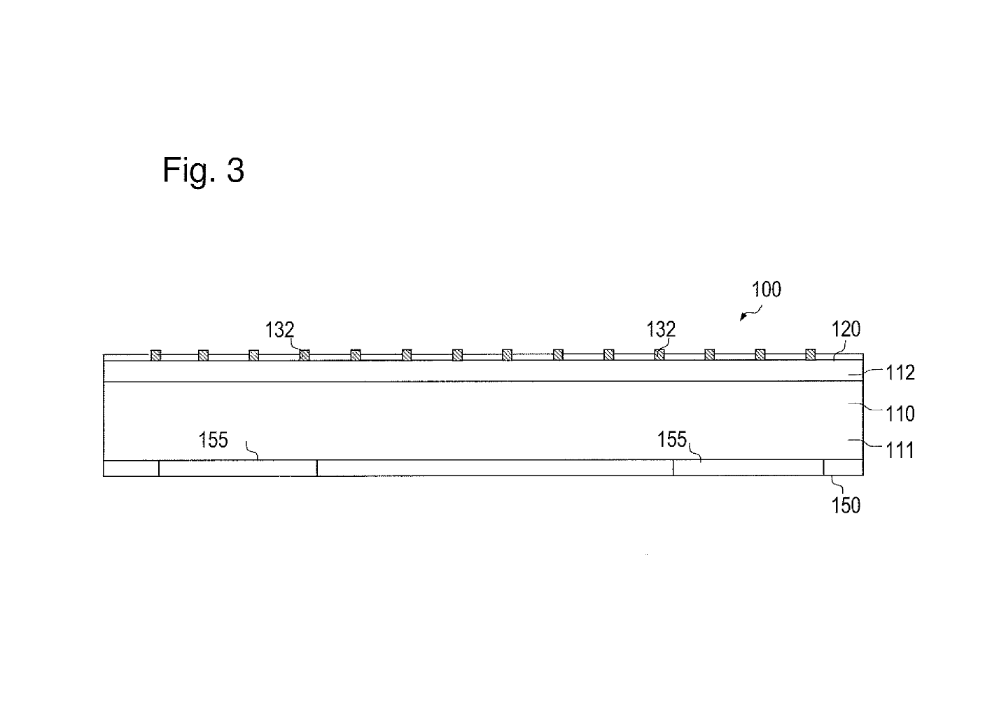

FIG. 3 shows a schematic lateral representation of a silicon solar cell;

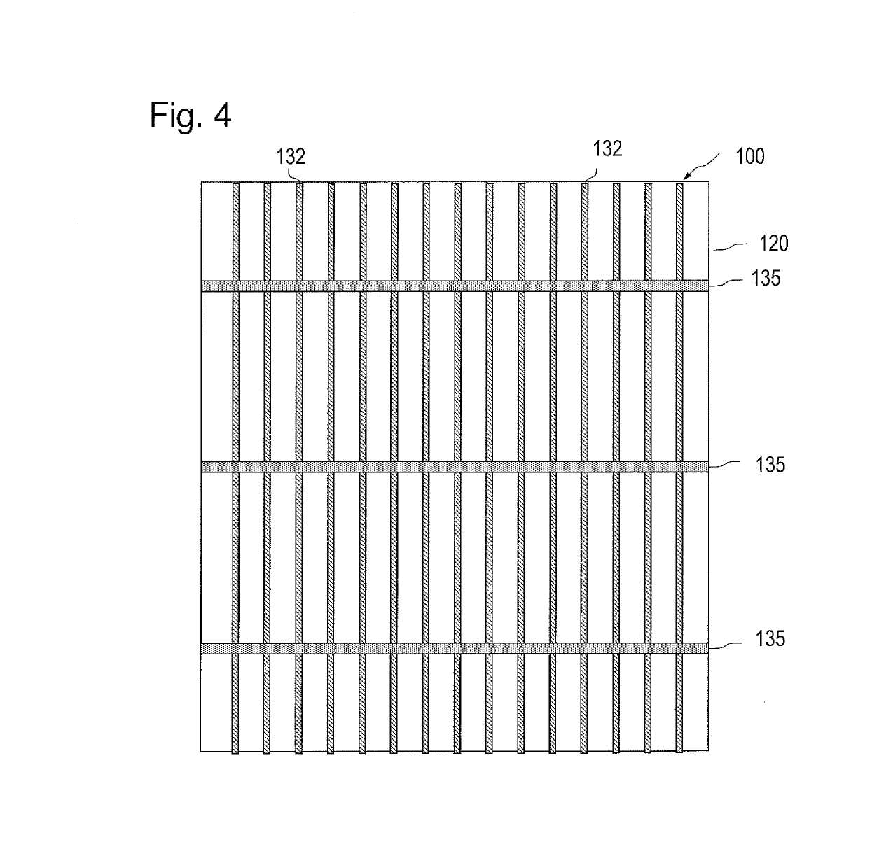

FIG. 4 shows a schematic representation of the front side of the silicon solar cell according to FIG. 3;

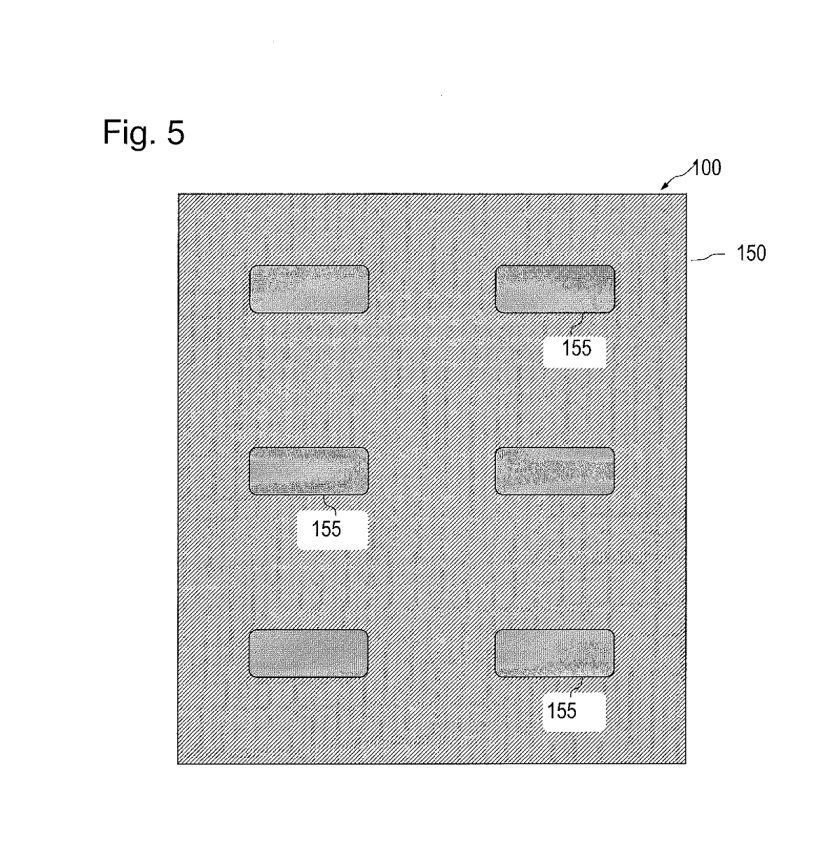

FIG. 5 shows a schematic representation of the rear side of the silicon solar cell according to FIG. 3; and

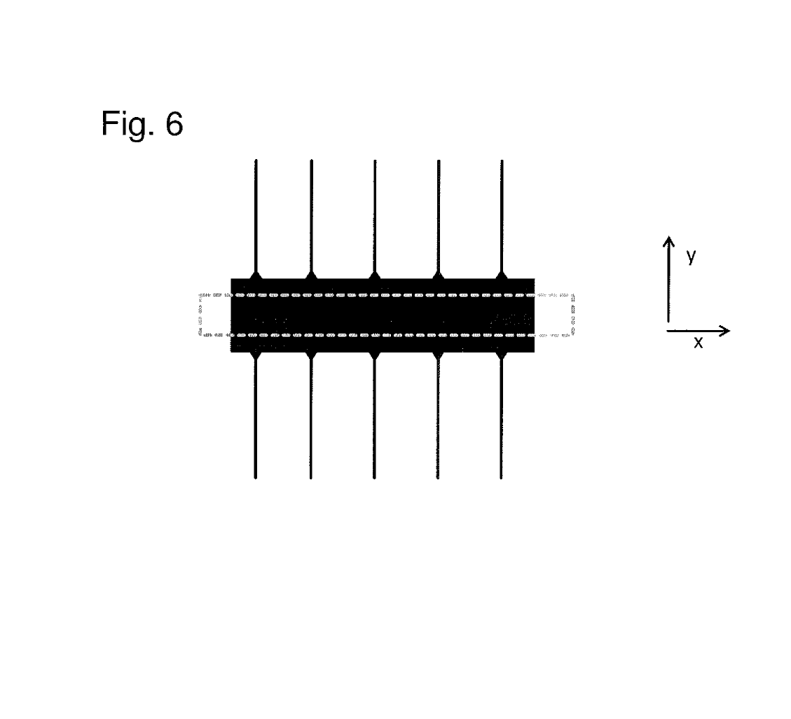

FIGS. 6 to 11 respectively show an embodiment of the front side contact structure of the silicon solar cell, wherein a respective section with a contact finger structure, a bus bar and an associated cell connector is shown.

With the help of the figures, a solar cell and a photovoltaic module are described, in which an improved front side contact structure of the solar cell ensures a reduction of finger breakages and cell breakages.

FIG. 1 shows a photovoltaic module 200 in a schematic lateral representation. An associated schematic top view, which illustrates the front side of the photovoltaic module, is represented in FIG. 2. The photovoltaic module 200—which is also referred to as solar module in the following—has a number of electrically interconnected silicon solar cells 100. During operation, the photovoltaic module 200 faces the solar radiation by its front side, wherein a portion of the radiation is absorbed by the solar cells 100 and is converted into electrical energy. Generally, the solar cells 100 have a square structure. However, other shapes are also possible. The solar cells 100—which are disposed in the photovoltaic module 200 in a plane—are located between a front side glass cover 210 and a rear side film cover 211 and are moulded into a transparent embedded layer 220. The photovoltaic module has a frame 230 at the edge, which imparts stability and the rigidity of connection to the module.

As FIG. 2 shows, the solar cells 100 of the photovoltaic module 200 are preferably interconnected in the form of a series connection, which extend S-shaped over the photovoltaic module 200. The interconnection takes place, as represented in FIG. 2, by means of cell connectors 240 which are configured in the shape of strip-like electric conductors, for example in the shape of tin-plated copper strips. The cell connectors 240 respectively connect a front side contact structure of a silicon solar cell with a rear side contact structure of an adjacent solar cell. The solar cells located outside, which are disposed in the shape of a matrix with gaps and lines on the photovoltaic module, are interconnected via cross-connectors 245.

FIG. 3 schematically shows a lateral representation or sectional representation of the solar cell 100 of the photovoltaic module 200. A top view on the front side of the solar cell 100 is shown in FIG. 4 and a rear side representation is shown in FIG. 5. The solar cell 100 has a silicon substrate 110, which is divided into a rear side base region 111 and a front side emitter region 112, which have different doping. Therefore, the base region 111 generally has a p-doping; whereas the emitter region 112 has an n-doping. A p-n-junction—which generates an electrical field—is formed between both the regions. By an irradiation of the solar cell, the charge carriers generated by absorption of radiation are then separated from each other by this electrical field. The contact structures are provided on the front side and the rear side of the solar cell in order to connect to the base region 111 and the emitter region 112.

Therefore, the front side contact structure includes a plurality of metallic contact elements, which are subsequently also referred to as contact fingers. These are configured—as shown in the FIG. 4—relatively thin and linear and extend over the solar cell in the shape of a parallel grid. The contact finger structure leads to just a slight shadowing of the solar cells front side, over which light radiation falls. The contact fingers 132 are preferably embedded in an anti-reflection layer 120, whereby the light reflection is suppressed on the surface, which minimizes the luminous efficacy. In addition to the contact fingers 132 extending in parallel, the front side contact structure of the solar cell preferably includes a number of metallic bus bars 135, which are also referred to as busbars in the following. The bus bars 135 are disposed perpendicular to the linear contact fingers 132 and extend out over the contact fingers. The bus bars 135 combine the charge carriers detected over the contact fingers from the emitter region 112 and forward them via the cell connector to the adjacent solar cells. The contact fingers 132 and the bus bars 135 are preferably composed of silver and are normally applied by means of a printing process, in which silver paste is used.

The rear side contact structure of the solar cell includes, as FIG. 5 shows, a metallic layer 150, on which a number of large surface metallic contact surfaces 155, are disposed preferably uniformly. The metallic layer 150 can be made of, for example aluminium, the metallic contact surfaces 155 can be composed of silver. The rear side contact surfaces 155 are used for the same purpose as the front side bus bars, for electrical and mechanical connection of the cell connector in the frame of the photovoltaic module in order to interconnect the individual solar cells in series connections. As in is shown further in FIG. 5, it is preferred to round-off or to chamfer the corners of the contact surfaces 155 in order to avoid stress peaks, which develop on sharp edges. Such stress peaks could lead to cell breakages.

While attaching the strip-like cell connector—which are generally copper strips—on the front side busbars, the mass production processes of the solar cells often result in inaccurate positioning of the cell connector, whereby then the cell connector moved against the busbars rests on the contact fingers. Through this contact, then forces in the contact fingers are coupled, e.g. by the different coefficients of thermal expansion of silicon substrate, silver paste, solder, for attaching the copper strips, copper, encapsulation material, rear side film or glass cover on the front side. This mechanical stress on the contact finger, which develops during the manufacturing processes, e.g. during cooling of the solder and the subsequent lamination process, or even by temperature fluctuation during solar cells operation, can then lead to damages to the contact fingers, particularly lead to breakages, which has a negative effect on the photovoltaic module output.

Such finger breakages and cell breakages are prevented by the improved front side contact structures in accordance with the invention, in which the continuous busbars schematically shown in FIG. 4 are divided into contact surfaces, which are respectively disposed in the region of the contact fingers and protrude above the contact fingers. The width of the strip-like cell connector extending over the bus bars is then smaller than the contact surfaces of the bus bars. Thus, the contact surfaces of the bus bars reliably shield the cell connector from the narrow and therefore sensitive contact fingers, even if the cell connectors are not accurately positioned. The lateral protrusion of the contact surfaces of the bus bars with respect to the strip-like cell connector extending thereon, is used for a sufficient tolerance range.

Configurations possible in accordance with the invention, of the front side contact structures in accordance with the invention are schematically represented in the FIGS. 6 to 11, wherein only one section is always shown. Therefore, the contact fingers 132 extend parallel to each other in Y-direction, whereas the bus bar 135 is disposed transverse to it in X-direction. The cell connector 240 disposed on the bus bar by the interconnection of the solar cells to the photovoltaic module is shown in dotted lines.

In the embodiment shown in FIG. 6, the individual contact surfaces of the bus bar—which are disposed over the contact fingers—are interconnected, so that a continuous bus bar results, which is configured wider than the cell connector extending thereon. Therefore, the continuous bus bar facilitates an excellent electrical and mechanical connection to the cell connector. The transition between the contact surfaces of the bus bars and the contact fingers is—as shown further in FIG. 6—configured chamfered, in order to avoid stress peaks during electrical transition between the contact fingers and the contact surfaces. Alternatively, there is also the possibility to round-off the corners—as in the rear side contact surfaces—in order to suppress the stress peaks.

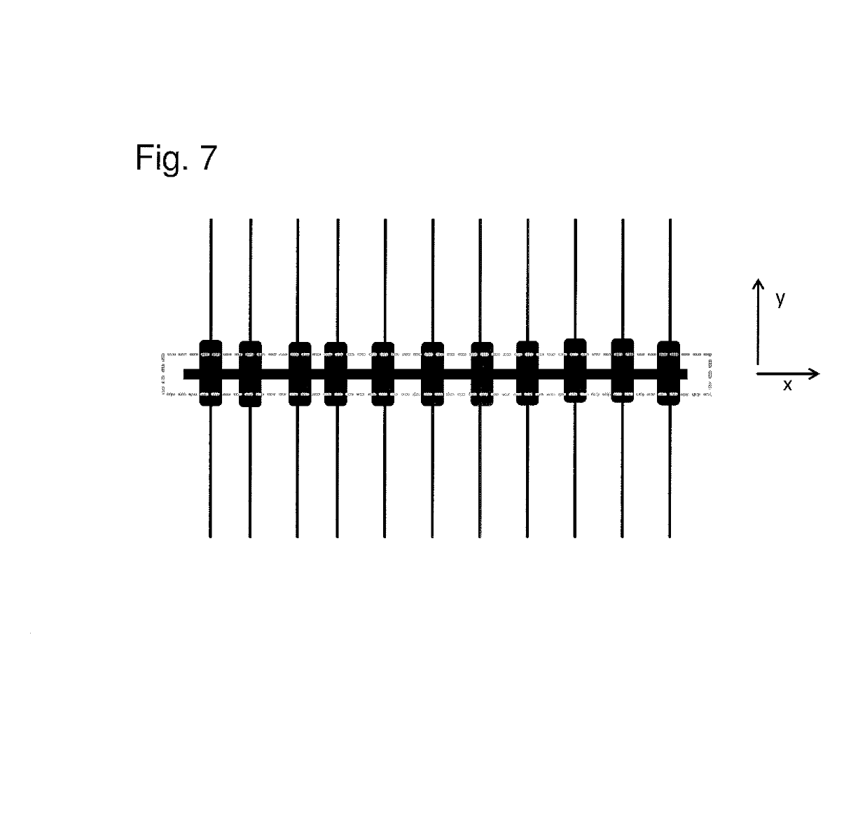

FIG. 7 shows another embodiment of the front side contact structure, in which the individual contact surfaces of the bus bars which have rounded off corners; are interconnected by means of a web. As a result, the additional web between the contact surfaces is used for an improved electrical and mechanical connection of the cell connector, wherein the reduced width of the web, with respect to the embodiment in FIG. 6 is used for a reduced material consumption of the bus bars generally composed of silver, and thereby for a reduction of the manufacturing costs.

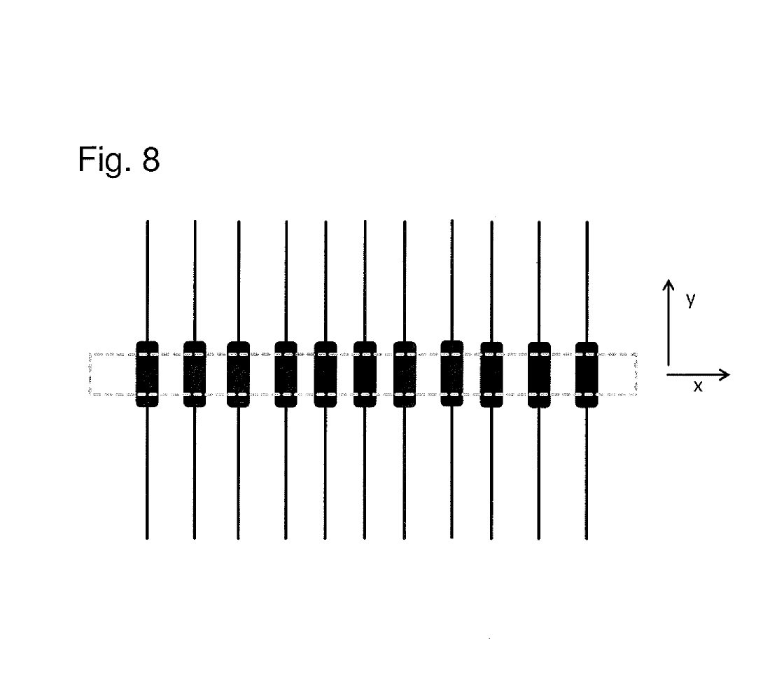

Another embodiment is shown in FIG. 8, in which the contact surfaces of the bus bar are configured separate from each other and interconnected only by the cell connectors extending in parallel thereon. With this configuration, the material consumption of the bus bar is further reduced and thereby a cost-effective manufacture is facilitated. Another advantage of the reduced metallizing surface in the region of the busbar, as it is shown in FIGS. 7 and 8, is made into better passivation of the cell surface, because the surface passivation of the emitter is preserved in the non-metallized regions.

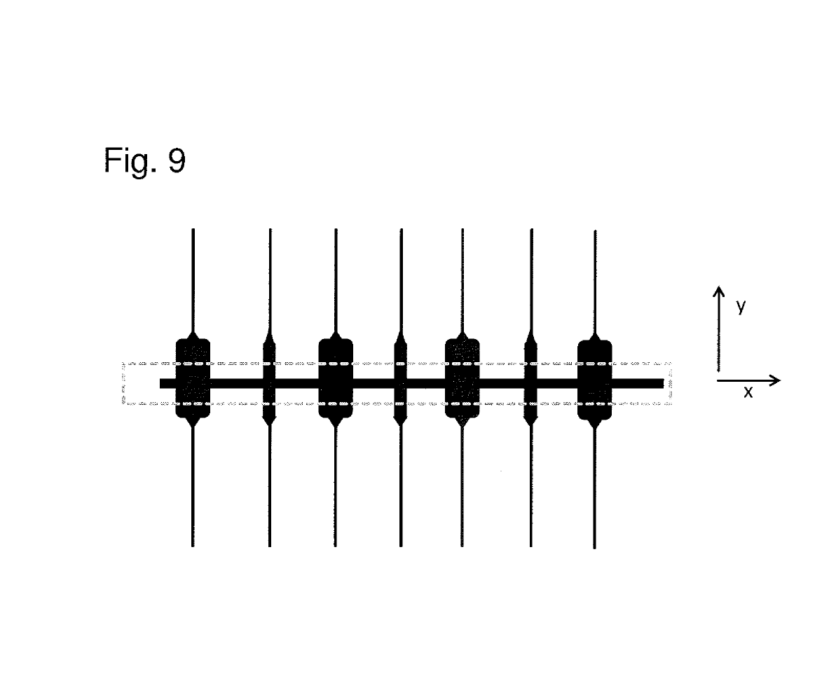

This also applies for the embodiment shown in FIG. 9, in which in Y-direction same width, but in X- direction alternating short and long contact surface are disposed over the contact fingers. The short contact surfaces are used for reducing the material input and at the same time for a sufficient electrical contact. The longer contact surfaces located therebetween ensure the mechanical connection of the cell connector to the bus bar, in order to avoid a withdrawal of the cell connectors from the bus bar at mechanical stress. The surface on the solar cell front side covered by the bus bars are reduced further by the short contact surfaces, whereby a reduced shielding and thereby an improved light input is achieved.

In principle, most diverse sequences of short and long contact surfaces can be conceived. For example, rather than as shown in FIG. 9, each second only third or fourth contact surface can be configured longer. In the integrated contact surfaces shown in FIG. 8, the Length of the contact surface is preferably 0.7 mm in X- direction, whereby a sufficient adhesion for the cell connector results. In the alternating contact surface lengths shown in FIG. 9, the length of the longer contact surface is 1 mm, that of the short contact surface is 0.3 mm, in order to offer a sufficient adhesion of the cell connector on the bus bars against the pulling-off forces.

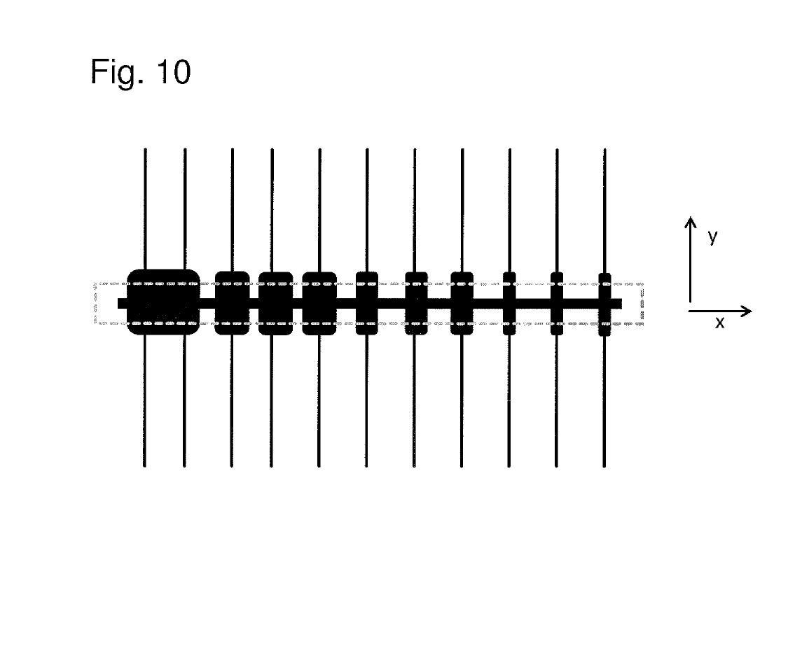

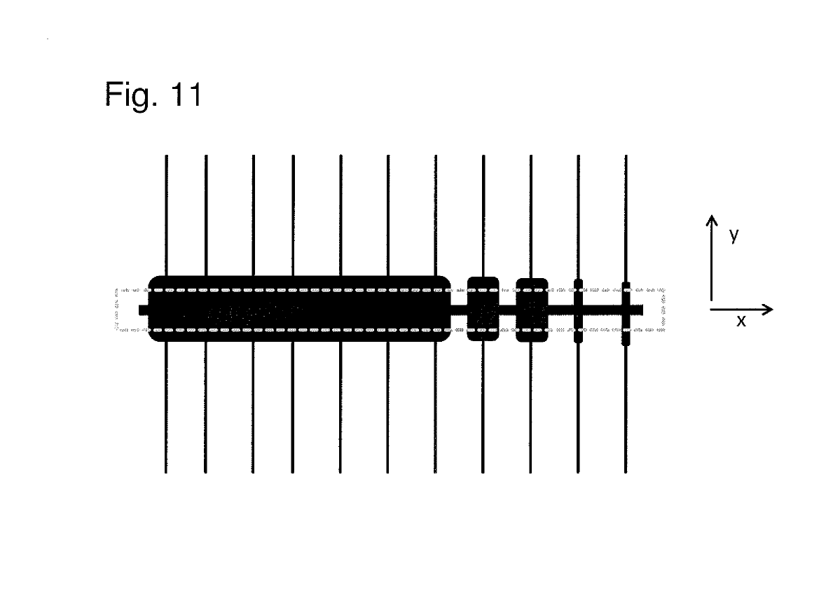

Alternatively, as shown in the FIGS. 10 and 11, even a sequence of contact surfaces can be used, the length of which reduces in X-direction, that is, in the direction of the cell connector. Therefore, as shown in FIG. 10, a stepped decrease in length of the contact surfaces can be configured or even a significant decrease as shown in FIG. 11. Further, the contact surfaces can overlap—as shown in FIGS. 10 and 11—more and more contact fingers. Therefore, it is preferred to configure a decrease in the lengths of the contact surfaces such that the contact surfaces located on the edge of the solar cell have the maximum lengths, because the strongest mechanical forces are exerted here on the cell connector during the manufacture and thus there is the greatest risk for peeling-off of the cell connector. Then, the largest contact surfaces are used for a better mechanical connection. Furthermore, it is preferred that the smallest contact surfaces are to be provided in the region of the center of the solar cell, since the least mechanical loading is subjected here on the cell connectors. Then, material can be saved as well as the shielding against the light input can be reduced by the reduced surface area.

1. Photovoltaic module, having:
a) a number of Solar cells made of pre-processed silicon wafers, which respectively have a contact structure that includes a number of linear contact fingers disposed in parallel in a first direction and at least one bus bar disposed perpendicular to the first direction, wherein the bus bar extends over the contact finger in a second direction and is electrically connected to the number of contact fingers, and
b) at least one cell connector for connecting the solar cells, which extends over the bus bar at least of one solar cell in the second direction and is electrically connected to the bus bar, wherein the width of the cell connector is smaller than the width of the bus bar.
wherein, the bus bar has a sequence of contact surfaces with different lengths in the second direction, which make the electrical connection with the contact finger, wherein the length of a contact surface of the bus bar which is disposed in the edge region of the solar cell, is greater in the second direction than the length of a contact surface of the bus bar which is disposed in the middle region of the solar cell in the second direction.

2. Photovoltaic module according to claim 1, wherein at least one of the contact surfaces of the bus bar extends in the second direction over a number of contact fingers.

3. Photovoltaic module according to claim 1, wherein the length of the contact surface of the bus bar of the solar cell in the second direction increases from the middle region towards the edge region.

4. Photovoltaic module according to claim 1, wherein a contact surface of the bus bar which is disposed in the middle region of the solar cell, is the minimum surface covering the remaining contact surfaces.

5. Photovoltaic module according to claim 1, wherein the corners of the contact surface are configured rounded-off or chamfered.

6. Photovoltaic module according to claim 1, wherein the transitions of the contact surfaces into the contact fingers are configured rounded-off or chamfered.

7. Photovoltaic module according to claim 1, wherein the bus bar has webs, which are narrower than the contact surfaces and interconnect these.

8. Photovoltaic module according to claim 7, wherein the transition of the contact surface of the bus bar into the webs is configured rounded-off or chamfered.

9. Photovoltaic module according to claim 1, further having a front glass cover and a rear side cover, wherein the solar cells are disposed between the front and rear side cover in an embedded layer, and wherein the solar cells with cell connector are connected to a number of lines of solar cells connected in series.
